(19) United States
(12) Patent Application Publication
(10) Pub. No.: US 2015/0008976 A1
(43) Pub. Date: Jan. 8, 2015

(54) ANTI-FUSE AND METHOD FOR OPERATING THE SAME

(71) Applicant: SK HYNIX INC., Icheon (KR)

(72) Inventor: Sung Su KIM, Incheon (KR)

(73) Assignee: SK HYNIX INC., Icheon (KR)

(21) Appl. No.: 14/192,571

(22) Filed: Feb. 27, 2014

(30) Foreign Application Priority Data
Jul. 3, 2013 (KR) 10-2013-0077886

(51) Int. Cl. H01L 23/525

(52) U.S. Cl. CPC H01L 23/5252
USPC 327/525; 257/379

(57) ABSTRACT

An anti-fuse includes a single transistor formed over an active region of a semiconductor substrate and entering a fuse cut state by a threshold voltage being varied upon receiving a voltage applied thereto. The single transistor includes a device isolation film formed in the semiconductor substrate to define the active region, and a liner trap film formed between the device isolation film and the active region in such a manner that electrons are trapped in the liner trap film upon receiving the voltage.

### CROSS-REFERENCE TO RELATED APPLICATION

The priority of Korean patent application No. 10-2013-0077886 filed on 3 Jul. 2013, the disclosure of which is hereby incorporated by reference in its entirety, is claimed.

### BACKGROUND

Embodiments of the present invention relate to an anti-fuse and a method for operating the same, and more particularly to a technology for an anti-fuse including one transistor.

As computers have come into widespread use, a semiconductor device that can operate at a high speed and having a high storage capacity is increasingly in demand. Therefore, technology for manufacturing a semiconductor device has been developed to improve the degree of integration, reliability, response speed, etc. of the device.

However, cells of a semiconductor device may have defects that occur in the process of manufacturing the semiconductor device. The defective cells may be detected in early stages of the manufacturing process, and are replaced with redundancy cells by a repair process.

Anti-fuses are needed for such a repair process. Anti-fuses offer a variety of advantages. For example, anti-fuses may allow the repair process to be performed at a package level, increase the number of net dies that can be repaired at a time, improve product characteristics. Because of the above-mentioned advantages of anti-fuses, anti-fuses may be widely used in various technical fields.

### SUMMARY

Various embodiments are directed to providing an anti-fuse and a method for operating the same, which substantially obviate one or more problems due to limitations and disadvantages of the related art.

Embodiments relate to an anti-fuse including a select transistor, which is configured to provide a ruptured fuse effect using a hot electron induced punch through (HEIP) phenomenon, and a method for operating the anti-fuse.

In accordance with an aspect of the embodiment, An anti-fuse array comprises a plurality of anti-fuses each of which includes a single transistor entering a fuse cut state by a threshold voltage being varied upon receiving a voltage applied thereto, wherein the single transistor comprises: a device isolation film disposed in a substrate to define an active region; and a liner trap film disposed between the device isolation film and the active region, wherein electrons are trapped in the liner trap film upon receiving the voltage.

The single transistor further comprises: a sidewall oxide film disposed between the liner trap film and the active region. The liner trap film includes a nitride film. The single transistor may be a select transistor of an anti-fuse.

The single transistor further comprises: a gate electrode disposed over the active region; a first source/drain junction disposed at a first side of the active region; and a second source/drain junction disposed at a second side of the active region, wherein the first source/drain junction and the second source/drain junction are disposed at opposing sides of the gate electrode.

The single transistor further comprises: a gate insulation film disposed between the gate electrode and the active region.

If the single transistor is a PMOS transistor, the single transistor enters the fuse cut state by a reduction in the threshold voltage.

If the single transistor is an NMOS transistor, the single transistor enters the fuse cut state by an increase in the threshold voltage

The sidewall oxide film has a thickness of about 40 nm to about 60 nm.

In accordance with another aspect of the embodiment, a method for operating an anti-fuse which includes a single transistor, the method comprising: operating the single transistor in a reverse bias condition when the anti-fuse operates in a fuse cut mode; and operating the single transistor in a forward bias condition when the anti-fuse operates in a fuse uncut mode, wherein the single transistor comprises a gate electrode, a source electrode, a drain electrode, and a liner trap film disposed between a device isolation film and an active region, and wherein a threshold voltage of the single transistor is varied by electrons trapped in the liner trap film in the fuse cut mode.

If the single transistor is a PMOS transistor, the anti-fuse operates in the fuse cut mode when electrons are trapped in the liner trap film and the threshold voltage of the single transistor is reduced.

If the single transistor is an NMOS transistor, the anti-fuse operates in the fuse cut mode when electrons are trapped in the liner trap film and the threshold voltage of the single transistor is increased.

The anti-fuse operates in the fuse cut mode if a voltage of about −5V is applied to the gate electrode, a voltage of about 0V is applied to the source electrode, and a voltage of about −5V is applied to the drain electrode.

The anti-fuse array operates in the fuse uncut mode if a voltage of about −0.5V is applied to the gate electrode, a voltage of about 0V is applied to the source electrode, and a voltage of about −1.5V is applied to the drain electrode.

The single transistor may be a select transistor of the anti-fuse. The single transistor further comprises a sidewall oxide film disposed between the liner trap film and the active region. The liner trap film includes a nitride film.

It is to be understood that both the foregoing general description and the following detailed description of embodiments are not limiting, but are intended to provide further explanation of the invention as claimed.

### BRIEF DESCRIPTION OF THE DRAWINGS

FIG. 1 illustrates a cross-sectional view (ii) and a plan view (i) of an anti-fuse according to an embodiment of the present invention.

FIG. 2 illustrates a cross-sectional view (ii) and a plan view (i) showing electrons trapped in the anti-fuse of FIG. 1.

FIG. 3 is a graph illustrating a variation of a threshold voltage when electrons are trapped in an anti-fuse.

FIGS. 4 and 5 are conceptual views illustrating an operation of an anti-fuse according to an embodiment of the present invention.

FIGS. 6A to 6F are cross-sectional views illustrating a method for forming an anti-fuse according to an embodiment of the present invention.

### DESCRIPTION OF EMBODIMENTS

Reference will now be made in detail to certain embodiments, examples of which are illustrated in the accompanying drawings. Wherever possible, the same reference numbers will be used throughout the drawings to refer to the same or like parts. In the following description, a detailed description of related known configurations or functions incorporated herein will be omitted when it may make the subject matter less clear.

In general, an anti-fuse array includes a plurality of program transistors, a plurality of select transistors, and a plurality of metal contacts. In the anti-fuse array, a program transistor, a select transistor, and a bit line (metal contact) are selected to program a cell that will replace a defective cell.

If a high voltage is applied to a program gate of the program transistor, a gate insulation film of the program transistor is ruptured due to the voltage difference between the high voltage and a low voltage received through the bit line. In this case, if a predetermined voltage is applied to a select gate of the select transistor, a channel region is formed below the select gate, such that the high voltage applied to the program gate is output not only through a channel of the select gate but also through the bit line located at a side of the select gate.

Embodiments of the present invention provide an anti-fuse including a select transistor, but no program transistor. In an embodiment, an anti-fuse is capable of operating without a program transistor by using a hot electron induced punch through (HEIP) phenomenon that reduces a threshold voltage of the select transistor.

The HEIP phenomenon indicates that electrons generated by a hot carrier effect are trapped at an interface between an oxide film and a nitride film such that a threshold voltage of the select transistor is reduced, resulting in the occurrence of a punch through effect in the select transistor.

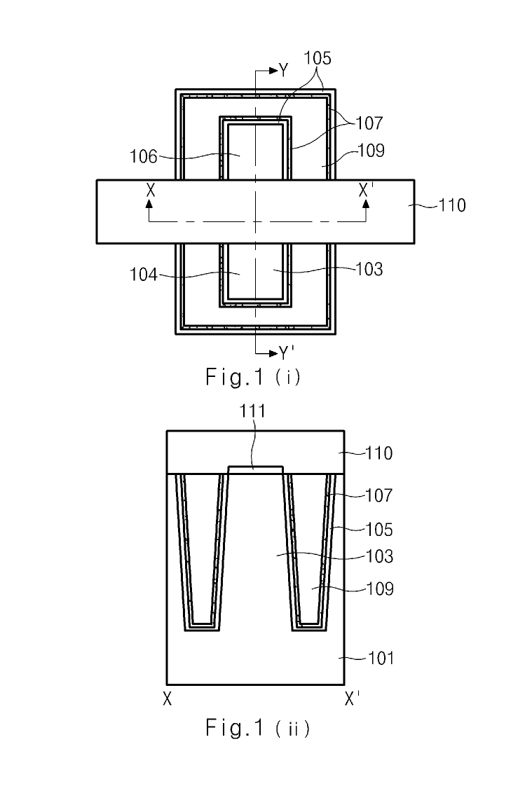

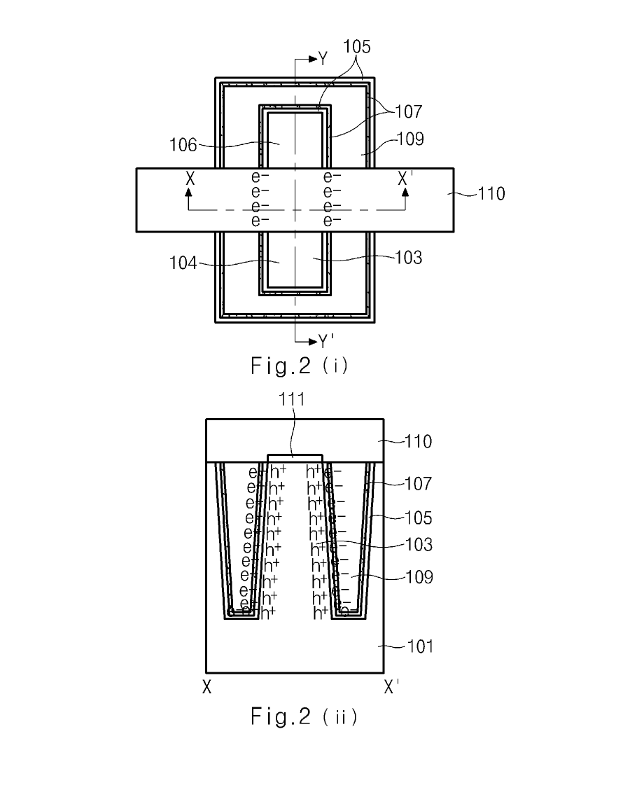

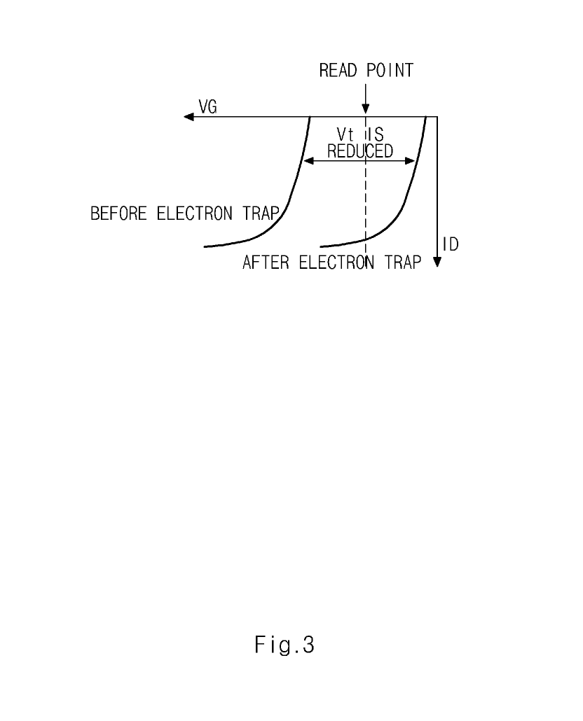

In FIG. 1, (i) and (ii) are a plan view and a cross-sectional view, respectively, illustrating an anti-fuse according to an embodiment of the present invention. In FIG. 2, (i) and (ii) are a plan view and a cross-sectional view, respectively, showing electrons trapped in the anti-fuse of FIG. 1. FIG. 3 is a graph illustrating a variation of a threshold voltage when electrons are trapped in the anti-fuse. In FIGS. 1 and 2, although a portion of a semiconductor substrate 101, which is disposed on a sidewall oxide film 105, is not shown in (i), the portion of the semiconductor substrate 101 is shown in (ii) for convenience of description.

Referring to FIG. 1, the anti-fuse includes an active region 103 enclosed by a device isolation film 109, and a gate electrode 110 formed over the active region 103 and the device isolation film 109 in the direction of an X-axis. In the anti-fuse, a gate insulation film 111 is disposed between the active region 103 and the gate electrode 110. A sidewall oxide film 105 and a liner trap film 107 are sequentially formed on sidewalls and the bottom of a device isolation region in which the device isolation film 109 is to be formed. The remaining portion of the device isolation region is filled with an insulation film to form the device isolation film 109.

Referring to FIG. 2, if a voltage is applied to the anti-fuse, electrons (e−) are trapped at an interface between the sidewall oxide film 105 and the liner trap film 107 within the device isolation region.

Since hot carriers of a transistor have high energy, the hot carriers easily penetrate into the device isolation film 109 after passing through the sidewall oxide film 105. In this case, most of the hot carriers penetrating into the device isolation film 109 are electrons (e), and thus the electrons (e) are easily trapped at the interface between the liner trap film 107 and the sidewall oxide film 105.

If the sidewall oxide film 105 is formed to have a small thickness and trapped electrons are dense in the device isolation film along a portion of a sidewall of the device isolation film 109 that is closest to the active region 103, holes (h+) in the active region 103 leak through the sidewall of the device isolation film 109. In addition, since electrons are also trapped at the interface between the liner trap film 107 and the sidewall oxide film 105, holes in the active region 103 are dense along a portion of a sidewall of the active region 103 that is closest to the sidewall oxide film 105. In embodiments, the distance between the active region 103 and the liner trap film 107 may be adjusted so that the density of trapped electrons can be adjusted. The distance between the active region 103 and the liner trap film 107 is determined by a thickness of the sidewall oxide film 105. The thickness of the sidewall oxide film 105 may be in a range of about 40 nm to about 60 nm. In an embodiment, the thickness of the sidewall oxide film 105 is minimized so that the density of trapped electrons can be maximized. The holes (h+) collecting at the portion of the sidewall closest to the sidewall oxide film 105 are used as a current path to interconnect two source/drain junctions, e.g., a source region 104 and a drain region 106, which are spaced apart from each other on either side of the gate electrode 110. As a result, a threshold voltage (Vt) of a transistor, e.g., a PMOS transistor, which includes the source region 104, the drain region 106, and the gate electrode 110, is reduced.

FIG. 3 is a graph showing a variation of a threshold voltage (Vt) when electrons are trapped in an anti-fuse including a PMOS transistor. In FIG. 3, ‘VG’ of the horizontal axis denotes a voltage applied to the gate electrode, and ‘ID’ of the vertical axis denotes a current flowing through the transistor.

If a voltage having the absolute value that is equal to or higher than that of a predetermined voltage is applied to a gate electrode when the predetermined voltage is applied to a drain electrode and a source electrode, the transistor is turned on at a specific point. In this case, the specific point is referred to as a read point. However, assuming that a HEIP phenomenon occurs as described above, a channel length becomes shorter because of the electrons trapped, and thus a threshold voltage is reduced. Therefore, although a voltage lower than a gate voltage required for a normal operation is applied to the gate electrode, the transistor may be turned on. That is, as shown in FIG. 3, if electrons are trapped, the read point moves to a lower voltage.

As described above, the HEIP phenomenon occurs in the select transistor of the anti-fuse, electrons are trapped in the vicinity of the liner trap film 107 and the sidewall oxide film 105, and a threshold voltage of the select transistor is lowered. As a result, an operational characteristic of the select transistor is deteriorated, and thus the effect on the select transistor is substantially the same as if fuse cutting had been performed.

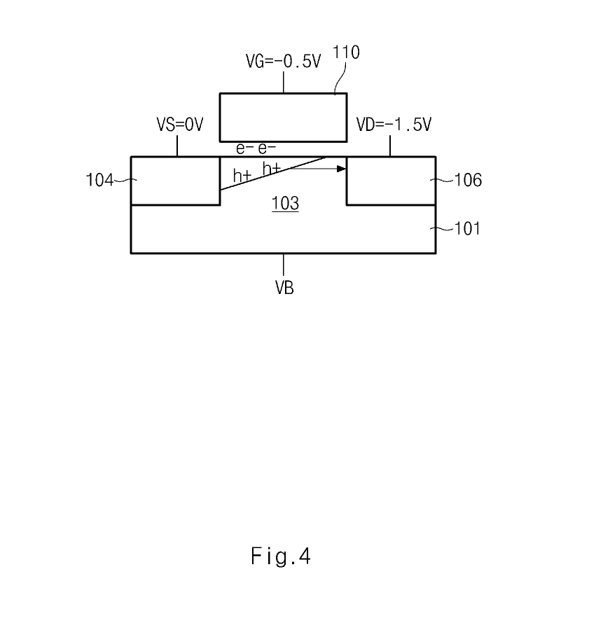

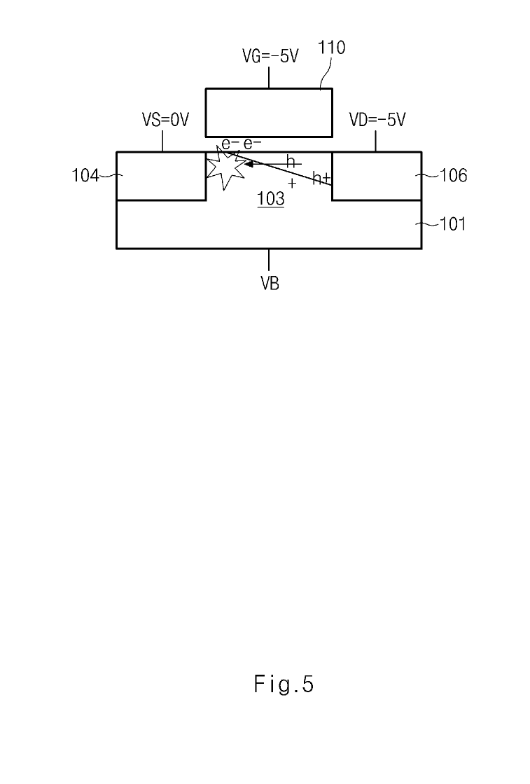

FIGS. 4 and 5 are conceptual views illustrating an operation of an anti-fuse including a PMOS transistor as a select transistor. Table 1 shows voltage conditions for modes of operation of an anti-fuse according to an embodiment of the present invention. Although Table 1 includes specific voltage values for convenience of illustration, embodiments of the present invention are not limited to these specified values. Operation of an anti-fuse according to an embodiment of the present invention will be described with reference to FIGS. 4 and 5 and Table 1.

TABLE 1

| Fuse | VG | VD | VS | Status |
|---|---|---|---|---|
| Fuse uncut | −0.5 V | −1.5 V | 0 V | |
| mode | | | | |
| Fuse cut mode | −5 V | −5 V | 0 V | HEIP |
| | | | | phenomenon |

Referring to FIG. 4, in a fuse uncut mode, a voltage of 0V is applied to a source region 104, a voltage of −1.5V is applied to a drain region 106, and a voltage of −0.5V is applied to a gate electrode 110. As a result, the anti-fuse is driven in a forward bias condition in which electric charges move from the source region 104 to the drain region 106.

Referring to FIG. 5, in a fuse cut mode, a voltage of 0V is applied to the source region 104, a voltage of −5V is applied to the drain region 106, and a voltage of −5V is applied to the gate electrode 110. Therefore, electrons are trapped in a portion of the liner nitride film 107 adjacent to the source region 104 and a punch through effect occurs. As a result, the anti-fuse operates as if it was turned on. In other words, the anti-fuse is driven in a reverse bias condition in the fuse cut mode. Although Table 1 shows optimum voltage conditions for the fuse cut mode, the scope and spirit of the embodiment is not limited thereto. It is possible to adjust the fuse cut mode of the anti-fuse by adjusting a voltage condition.

Referring to FIGS. 4 and 5, a bias condition applied to the anti-fuse in the fuse uncut mode is different from a bias condition applied to the anti-fuse in the fuse cut mode. As described above, in the fuse uncut mode, as shown in FIG. 4, the anti-fuse is in a forward bias status. On the other hand, in the fuse cut mode, as shown in FIG. 5, the anti-fuse is in a reverse bias status. As a result, although the anti-fuse is not actually cut, it is recognized that the anti-fuse operates as if it was in a cut fuse state.

As described above, the liner trap film 107 is formed between the device isolation film 109 and the active region 103 in such a manner that the HEIP phenomenon readily occurs in the select transistor of the anti-fuse. A voltage condition for the fuse uncut mode is different from a voltage condition for the fuse cut mode. In order to allow the select transistor to enter the fuse cut mode, the HEIP phenomenon intentionally induced in the select transistor by adjusting voltages applied to the source region 104, the drain region 106, and the gate electrode 110 of the select transistor. The select transistor in which the HEIP phenomenon occurs operates as if the anti-fuse was ruptured, such that it is recognized that the anti-fuse is turned on.

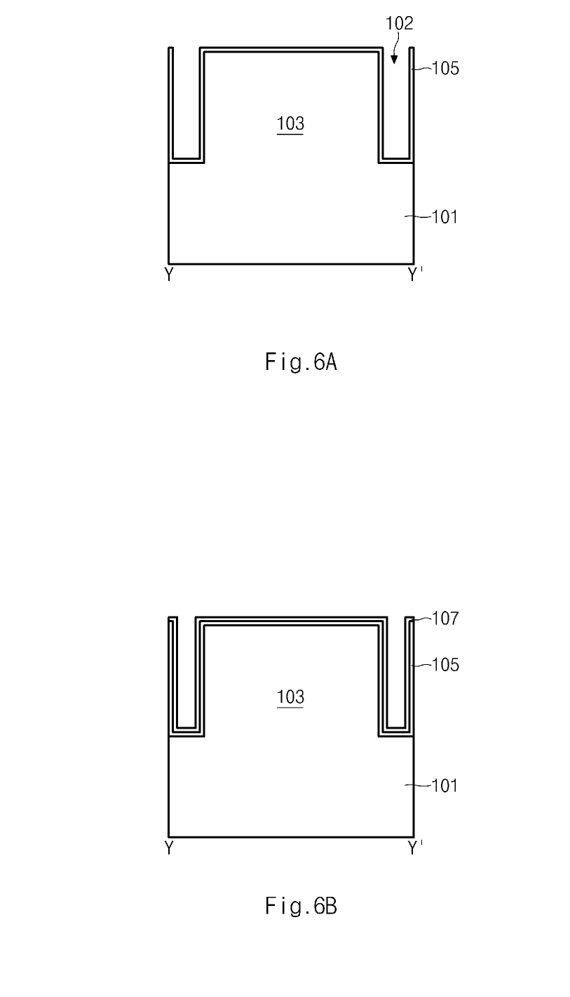

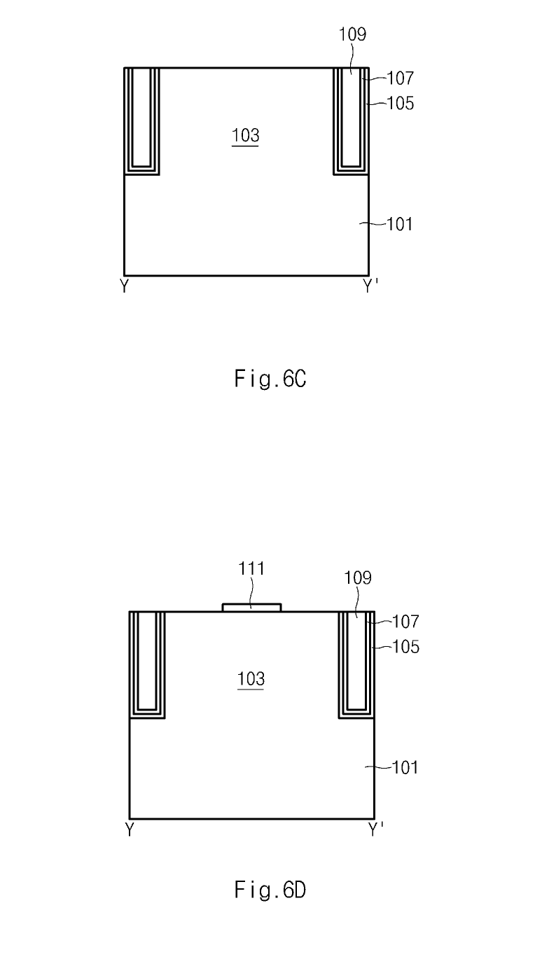

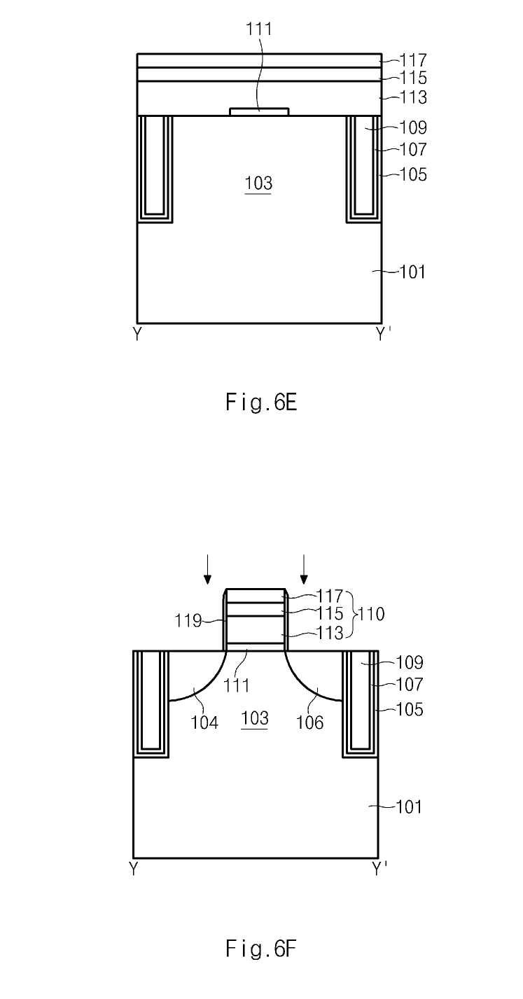

FIGS. 6A to 6F are cross-sectional views illustrating a method for forming an anti-fuse according to an embodiment of the present invention. The anti-fuse includes one transistor such as a PMOS transistor or an NMOS transistor.

Referring to FIG. 6A, a device isolation region 102 is formed by partially etching a semiconductor substrate 101 in such a manner that an active region 103 is defined in the semiconductor substrate 101 of a peripheral region. Subsequently, a sidewall oxide film 105 is formed at an upper portion and sidewalls of the active region 103 and the bottom of the device isolation region 102. In an embodiment, the sidewall oxide film 105 is formed by oxidizing an exposed portion of the semiconductor substrate 101. Here, this oxidation process may be achieved by implanting nitrogen (N₂) into the exposed portion of the semiconductor substrate 101 and performing thermal oxidation. The sidewall oxide film 105 may be formed to have a small thickness. In an embodiment, the sidewall oxide film 105 has a thickness of 40 nm to 60 nm to facilitate electron trapping. That is, the sidewall oxide film 105 may be formed to have a predetermined thickness in such a manner that the semiconductor substrate 101 and the sidewall oxide film 105 can maintain Si/SiO₂ properties, resulting in an increased trap site.

Referring to FIG. 6B, a liner trap film 107 is formed over the sidewall oxide film 105. The liner trap film 107 is formed of a material that facilitates electron trapping. In an embodiment, the line trap film 107 includes a nitride film such as a silicon nitride (Si₃N₄) film. The liner trap film 107 may be formed over the sidewall oxide film 105 using a chemical vapor deposition (CVD).

Referring to FIG. 6C, an insulation material fills the remaining portion of the device isolation region 102 in which the sidewall oxide film 105 and the liner trap film 107 are formed. As a result, a device isolation film 109 is formed in the device isolation region 102. In an embodiment, a device isolation material, i.e., the insulation material, is deposited by a high density plasma (HDP) deposition process using a silicon source and an oxygen (O₂) gas. After that, a planarization process is performed on the deposited device isolation material until the top surface of the active region 103 is exposed. The planarization process is performed using chemical mechanical polishing (CMP).

Referring to FIG. 6D, a gate insulation film 111 is formed over the active region 103. In an embodiment, the gate insulation film 111 is formed by performing heat oxidation on the active region 103.

Referring to FIG. 6E, a first gate electrode material 113 and a second gate electrode material 115 are sequentially deposited over the resultant structure including the gate insulation film 111, and a hard mask film 117 is deposited over the second gate electrode material 115. The first gate electrode material 113 and the second gate electrode material 115 may be formed of polymer, tungsten (W), titanium (Ti), tungsten nitride (WN), or a combination thereof. The hard mask film 117 may include a nitride film.

Referring to FIG. 6F, after a photoresist pattern (not shown) for forming a gate electrode 110 is formed over the hard mask film 117, the hard mask film 117, the second gate electrode material 115, and the first gate electrode material 113 are sequentially etched using the photoresist pattern as a mask. As a result, the gate electrode 110 is formed over the active region 103. The gate electrode 110 includes the etched hard mask film 117, the etched second gate electrode material 115, and the etched first gate electrode material 113. After that, a spacer 119 is formed on a sidewall of the gate electrode 110.

Thereafter, as shown in the plan view (i) of FIG. 1, ions are implanted into the exposed active region 103 using the gate electrode 110 as a mask, such that source and drain regions 104 and 106 are formed. In an embodiment, the source and drain regions 104 and 106 are thermally processed such that ions can be diffused into some parts of the active region 103 under a gate pattern including the gate insulation film 111 and the gate electrode 110.

Subsequently, although it is not shown in the drawings, an interlayer insulation film (not shown) is formed over an entire surface of the semiconductor substrate 101 including the gate electrode 110, and then a photoresist pattern (not shown) is formed over the interlayer insulation film. After that, the interlayer insulation film is etched such that metal contact holes (not shown) are formed over the gate electrode 110 and the source and drain regions 104 and 106.

As described above, electrons are trapped at an interface between the sidewall oxide film 105 and the liner trap film 107 of an anti-fuse, such that a threshold voltage of a PMOS transistor of the anti-fuse is reduced. As a result, the anti-fuse readily enters a cut fuse state.

The above embodiments disclose an anti-fuse for implementing a cut fuse state by using an HEIP phenomenon occurring in a PMOS transistor. In contrast, in another embodiment using an NMOS transistor as a select transistor of an anti-fuse, if electrons are trapped in the liner trap film 107 by the hot carrier phenomenon, a threshold voltage increases, and thus the anti-fuse including the NMOS transistor may operate as if it was a cut fuse. An anti-fuse according to embodiments of the present invention does not include a program transistor and uses only one select transistor. Therefore, it is possible to reduce a size of the semiconductor device.

In addition, if a read scheme of a flash memory is applied to an anti-fuse array, transistors in the anti-fuse array can be arranged in a NOR or NAND structure. As a result, it is possible to implement the anti-fuse array in a much smaller area than in a conventional fuse array having a structure for laser-based fuse cutting, and thus productivity of a semiconductor device is increased.

Those skilled in the art will appreciate that embodiments may be carried out in other specific ways than those set forth herein without departing from the spirit and essential characteristics of the present invention. The above embodiments are therefore to be construed in all aspects as illustrative and not restrictive. Embodiments should be determined by the appended claims and their legal equivalents, not by the above description, and all changes coming within the meaning and equivalency range of the appended claims are intended to be embraced therein. Also, claims that are not explicitly cited in each other in the appended claims may be presented in combination as an embodiment or included as a new claim by a subsequent amendment after the application is filed.

The above embodiments of the present invention are illustrative and not limitative. Various alternatives and equivalents are possible. The invention is not limited by the type of deposition, etching polishing, and patterning steps described herein. Nor is the invention limited to any specific type of a semiconductor device. For example, the present invention may be implemented in a dynamic random access memory (DRAM) device or non-volatile memory device. Other additions, subtractions, or modifications are obvious in view of the present disclosure and are intended to fall within the scope of the appended claims.

What is claimed is:

1. An anti-fuse array comprising:
a plurality of anti-fuses each of which includes a single transistor entering a fuse cut state by a threshold voltage being varied upon receiving a voltage applied thereto,
wherein the single transistor comprises:
a device isolation film disposed in a substrate to define an active region; and
a liner trap film disposed between the device isolation film and the active region,
wherein electrons are trapped in the liner trap film upon receiving the voltage.

2. The anti-fuse array according to claim 1, wherein the single transistor further comprises:
a sidewall oxide film disposed between the liner trap film and the active region.

3. The anti-fuse array according to claim 1, wherein the liner trap film includes a nitride film.

4. The anti-fuse array according to claim 1, wherein the single transistor is a select transistor of an anti-fuse.

5. The anti-fuse array according to claim 1, wherein the single transistor further comprises:
a gate electrode disposed over the active region;
a first source/drain junction disposed at a first side of the active region; and
a second source/drain junction disposed at a second side of the active region,
wherein the first source/drain junction and the second source/drain junction are disposed at opposing sides of the gate electrode.

6. The anti-fuse array according to claim 5, wherein the single transistor further comprises:
a gate insulation film disposed between the gate electrode and the active region.

7. The anti-fuse array according to claim 1, wherein:
if the single transistor is a PMOS transistor, the single transistor enters the fuse cut state by a reduction in the threshold voltage.

8. The anti-fuse array according to claim 1, wherein:
if the single transistor is an NMOS transistor, the single transistor enters the fuse cut state by an increase in the threshold voltage.

9. The anti-fuse array according to claim 2, wherein the sidewall oxide film has a thickness of about 40 nm to about 60 nm.

10. A method for operating an anti-fuse which includes a single transistor, the method comprising:
operating the single transistor in a reverse bias condition when the anti-fuse operates in a fuse cut mode; and
operating the single transistor in a forward bias condition when the anti-fuse operates in a fuse uncut mode,
wherein the single transistor comprises a gate electrode, a source electrode, a drain electrode, and a liner trap film disposed between a device isolation film and an active region, and
wherein a threshold voltage of the single transistor is varied by electrons trapped in the liner trap film in the fuse cut mode.

11. The method according to claim 10, wherein:
if the single transistor is a PMOS transistor, the anti-fuse operates in the fuse cut mode when electrons are trapped in the liner trap film and the threshold voltage of the single transistor is reduced.

12. The method according to claim 10, wherein:
if the single transistor is an NMOS transistor, the anti-fuse operates in the fuse cut mode when electrons are trapped in the liner trap film and the threshold voltage of the single transistor is increased.

13. The method according to claim 11, wherein:
the anti-fuse operates in the fuse cut mode if a voltage of about −5V is applied to the gate electrode, a voltage of about 0V is applied to the source electrode, and a voltage of about −5V is applied to the drain electrode.

14. The method according to claim 11, wherein:
the anti-fuse array operates in the fuse uncut mode if a voltage of about −0.5V is applied to the gate electrode, a voltage of about 0V is applied to the source electrode, and a voltage of about −1.5V is applied to the drain electrode.

15. The method according to claim 10, wherein the single transistor is a select transistor of the anti-fuse.

16. The method according to claim 10, wherein the single transistor further comprises a sidewall oxide film disposed between the liner trap film and the active region.

17. The method according to claim 10, wherein the liner trap film includes a nitride film.
